(19) United States
(12) Patent Application Publication
(10) Pub. No.: US 2023/0185686 A1
(43) Pub. Date: Jun. 15, 2023

(54) STORAGE SYSTEM AND OPERATING METHOD OF THE SAME

(71) Applicant: Samsung Electronics Co., Ltd., Suwon-si (KR)

(72) Inventors: Se Ho KIM, Uiwang-si (KR); Hye Ry NO, Seoul (KR)

(73) Assignee: Samsung Electronics Co., Ltd., Suwon-si (KR)

(21) Appl. No.: 17/879,974

(22) Filed: Aug. 3, 2022

(30) Foreign Application Priority Data
Dec. 13, 2021 (KR) 10-2021-0177392

(51) Int. Cl. G06F 11/263; G06F 11/22; G06F 1/30

(52) U.S. Cl. CPC G06F 11/263; G06F 11/2236; G06F 1/30

(57) ABSTRACT

A storage system and an operating method of the same are provided. A storage system may comprise, a host device including processing circuitry, a storage device configured to communicate with the host device, and the processing circuitry is configured to, generate a test power fault based on power fault setting information stored in a setting value table, and inject the test power fault into the storage device based on the power fault setting information.

### CROSS-REFERENCE TO RELATED APPLICATION

This U.S. non-provisional application claims the benefit of priority from Korean Patent Application No. 10-2021-0177392, filed on Dec. 13, 2021 in the Korean Intellectual Property Office, and all the benefits accruing therefrom under 35 U.S.C. 119, the contents of which in its entirety are herein incorporated by reference.

### BACKGROUND

### 1. Field of the Invention

Various example embodiments of the inventive concepts relate to a storage system and/or an operating method of the same.

### 2. Description of the Related Art

A power fault may occur in a storage device inside a storage system. The power fault may be, for example, a SPO (Sudden Power Off), a NPO (Normal Power Off), a LVDF (Low Voltage Fault F), and/or a LVDH (Low Voltage Fault H), etc.

A firmware that drives the storage device may be executed in preparation for a power fault that occurs in the storage device. However, when a power fault occurs in the storage device, it is desired and/or necessary to test whether the firmware is performed normally. Accordingly, there is a need for an ability to test to the firmware to determine whether the firmware operates as expected by intentionally injecting and/or causing the power fault into the storage device.

### SUMMARY

Various aspects of the example embodiments provide a storage system in which an operating verification accuracy of the firmware due to occurrence of the power fault is improved, in a simulation process when the power fault occurs.

However, aspects of the example embodiments of the inventive concepts are not restricted to the one set forth herein. The above and other aspects of the example embodiments of the inventive concepts will become more apparent to one of ordinary skill in the art to which the inventive concepts pertain by referencing the detailed description of the example embodiments of the inventive concepts given below.

According to an aspect of at least one example embodiment of the inventive concepts, there is provided a storage system comprising, a host device including processing circuitry, a storage device configured to communicate with the host device, and the processing circuitry is configured to, generate a test power fault based on power fault setting information stored in a setting value table, and inject the test power fault into the storage device based on the power fault setting information.

According to an aspect of at least one example embodiment of the inventive concepts, there is provided a storage system includes processing circuitry configured to execute computer readable instructions to, generate a test power fault based on power fault setting information, and inject the test power fault into a storage device.

According to an aspect of at least one example embodiment of the inventive concepts, there is provided a method for operating a storage system, the method comprising, storing, using processing circuitry, power fault setting information related to test power fault injection settings in a setting value table included in a host device, generating, using the processing circuitry, a test power fault based on the stored power fault setting information, injecting, using the processing circuitry, the test power fault into a storage device in accordance with the stored power fault setting information, detecting, using the processing circuitry, a trigger generated by the storage device in response to the injected test power fault, and inspecting, using processing circuitry, a recovery operation executed at the storage device in response to the test power fault.

### BRIEF DESCRIPTION OF THE DRAWINGS

The above and other aspects and features of the inventive concepts will become more apparent by describing in detail various example embodiments thereof with reference to the attached drawings, in which:

FIG. 1 is a block diagram which shows a storage system according to some example embodiments.

FIG. 2 is a block diagram which shows a part of the storage system according to some example embodiments.

FIG. 3 is an example graph for explaining some operation of the storage system according to some example embodiments.

FIG. 4 is a flowchart for explaining the operating method of the storage system according to some example embodiments.

FIG. 5 is an example block diagram for explaining an electronic system to which the operation of the storage system according to some example embodiments are applied.

### DETAILED DESCRIPTION

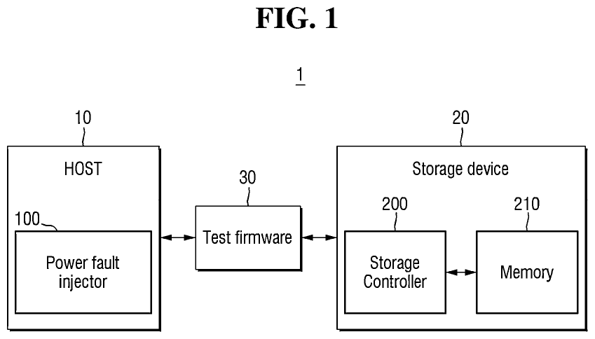

FIG. 1 is a block diagram which shows a storage system according to some example embodiments.

Referring to FIG. 1, a storage system 1 according to some example embodiments include a host 10, a storage device 20, and/or a test firmware 30, etc., but the example embodiments are not limited thereto, and for example, the storage system 1 may include a greater or lesser number of constituent components.

The host 10 (e.g., a host device, a host computer, an external device, etc.) may inject (and/or cause) a power fault into the storage device 20 through and/or using a power fault injector 100 and/or test firmware 30, etc., but is not limited thereto. In other words, the power fault injector 100 may generate a test power fault, transmit the generated test power fault to the test firmware 30, and the test firmware 30 may inject the generated test power fault into the storage device 20, but the example embodiments are not limited thereto, and for example, the power fault injector 100 may transmit the generated test power fault directly to the storage device 20, etc. According to some example embodiments, the test firmware 30 may be included in the host 10 (e.g., stored in memory (not shown) included in the host 10) and/or may be included in the storage device 20 (e.g., the memory 210, etc.), but the example embodiments are not limited thereto. For example, the test firmware 30 may be included in an independent device (not shown), such as an uninterruptible power supply (UPC) device, etc., but the example embodiments are not limited thereto. Additionally, the test firmware 30 may be executed by processing circuitry included in the host 10, the storage device 20, and/or the independent device, etc.

The storage device 20 includes a storage controller 200 (e.g., storage processing circuitry, etc.) and at least one non-volatile memory 210, etc., but is not limited thereto.

The storage device 20 may include at least one non-transitory storage medium for storing data in accordance with at least one request from the host 10, but is not limited thereto. For example, the storage device 20 may include at least one an SSD (Solid State Drive), an embedded memory, and/or a detachable external memory, etc. When the storage device 20 is the SSD, the storage device 20 may be, for example, a device that complies with a non-volatility memory express (NVMe) standard, but is not limited thereto. When the storage device 20 is an embedded memory or an external memory, the storage device 20 may be a device that complies with a UFS (universal flash storage) and/or an eMMC (embedded multi-media card) standard, but the example embodiments are not limited thereto. In some example embodiments, the storage device 20 may include a plurality of SSDs, a plurality of embedded memories, and/or a plurality of detachable external memories, etc., but is not limited thereto. The host 10 and the storage device 20 may each generate and transmit packets according to the adopted standard protocol(s) of the storage device 20.

When the non-volatile memory 210 of the storage device 20 includes a flash memory, the flash memory may include a 2D NAND memory array and/or a 3D (or vertical) NAND (VNAND) memory array. As another example, the storage device 20 may include different types of non-volatile memories. For example, a MRAM (Magnetic RAM), a spin-transfer torque MRAM, a conductive bridging RAM (CBRAM), a FeRAM (Ferroelectric RAM), a PRAM (Phase RAM), a resistive memory (Resistive RAM), etc., and/or various other types of memories may be adopted to the storage device 20, etc.

The storage controller 200 may control the overall operation of the storage device 20, but is not limited thereto.

The power fault injector 100 may record setting information about, corresponding to, and/or based on the power fault injection that is set by a user of the storage system 1 through, for example, the host 10, but is not limited thereto. The power fault injector 100 may generate and/or inject the power fault into the storage device 20 according to and/or based on the setting information about the power fault injection recorded by the user. According to at least one example may be implemented as and/or executed by processing circuitry included in the host 10, etc. More specifically, the power fault injector 100 may control a power supply (now shown) supplying power to the storage device 20 based on the setting information corresponding to the test power fault, thereby generating the test power fault which is injected and/or transmitted to the storage device 20 and/or desired components of the storage device 20, etc., but the example embodiments are not limited thereto.

That is, it is possible to improve the reliability of the operating performance verification of the firmware 30 that is expected when a power fault actually occurs (e.g., an actual power fault and/or a non-test power fault) in the storage device 20, by injecting the generated power fault (e.g., test power fault) into the storage device 20 based on the input and/or materialized setting value, and monitoring the operation of the test firmware 30 (e.g., monitoring the results of the test power fault injection, etc.) accordingly, etc., but the example embodiments are not limited thereto.

According to some example embodiments, the storage controller 200 and/or the power fault injector 100, etc., may each be implemented as processing circuitry. The processing circuitry may include hardware including logic circuits; a hardware/software combination such as a processor executing software and/or firmware, such as test firmware 30; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc., but is not limited thereto.

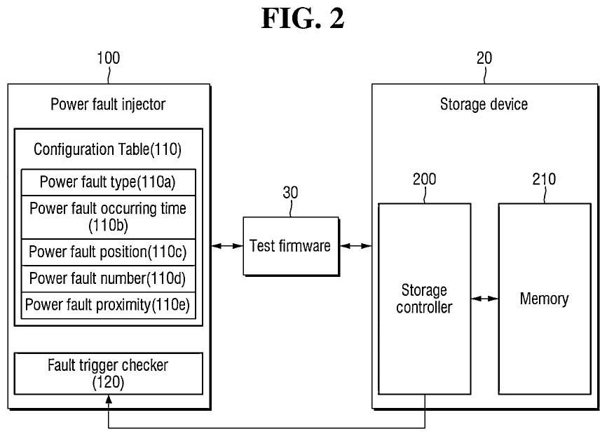

FIG. 2 is a block diagram which shows a part of the storage system according to some example embodiments.

Referring to FIGS. 1 and 2, the user of the storage system 1 may record the setting information, e.g., setting information 110a to 110e, etc., about the power fault (e.g., the test power fault, etc.), which is injected into the storage device 20 by the power fault injector, in the setting value table 110 (e.g., configuration table, etc.) of the host 10, but the example embodiments are not limited thereto.

The setting information 110a to 110e may include, for example, information about and/or including at least one of a type 110a of the power fault, a time point 110b at which the power fault is generated, a position 110c where the power fault occurs, number of times 110d by which the power fault occurs, and/or probability 110e at which the power fault occurs, etc., but is not limited thereto. Additionally, according to some example embodiments, the setting value table 110 may further include desired and/or expected results of the power fault to which to compare the results and/or response of the test firmware 30 and/or the storage device 20 to the injected test power fault, etc.

Specifically, the setting information stored in the setting value table 110 according to at least one example embodiment will be described below.

The type 110a of the power fault (e.g., a desired power fault type) setting may be, for example, a SPO (Sudden Power oft), a NPO (Normal Power Oft), a LVDF (Low Voltage Fault F), and/or a LVDH (Low Voltage Fault H), etc., but is not limited thereto.

The SPO may be a case where the power provided to the storage device 20 is reduced and/or turned off regardless of the user's intentions, e.g., due to a power outage at the storage device 20's physical location, etc.

The NPO may be a case where the power is intentionally turned off by, for example, a power management unit (for example, PMU) that manages the power of the user and/or the storage device 20, etc.

The LVDF may be a situation in which the power applied to the non-volatile memory 210 in the storage device 20 becomes lower than a reference value (e.g., a reference value set by the user and/or manufacturer of the non-volatile memory 210, etc.), and this status is detected by the power management unit (for example, PMU).

The LVDH may be a situation in which the power applied to the storage controller 200 (and/or the processing circuitry of the storage device 20, a central processing unit (CPU) included in the storage device 20, etc.) becomes lower than the reference value set by the user, and this status is detected by the power management unit (for example, PMU), but the example embodiments are not limited thereto.

The time point 110b at which the power fault occurs setting may be, for example, a desired setting value that is defined so that the power fault occurs at a certain time point (e.g., a desired time, a desired test time, etc.) specified by the user after the storage device 20 operates, for example, a time at which the user intends for the test power fault to be injected into the storage device 20, etc.

The position 110c where the power fault occurs setting may specify, for example, a specific position and/or component to which the power fault is injected by the power fault injector 100, but is not limited thereto. For example, the position 110c may indicate the desired position and/or desired component of the storage device 20 where the power fault is injected, occurs, and/or is tested, etc., such as, an ECC engine, a CPU, and/or a buffer in the storage controller 200, etc., but the example embodiments are not limited thereto. For example, the position 110c may indicate that the power fault is to occur in the non-volatile memory 210, etc.

The number of times 110d by which a power fault occurs setting may be, for example, the desired number of times by which the power fault injector 100 injects the power fault into the storage device 20, etc.

The probability 110e at which a power fault occurs setting may make, for example, a power fault occur at a probability rate specified by the user with respect to the number of times by which the firmware for driving the storage device 20 (for example, the test firmware 30, etc.) operates, etc., but is not limited thereto. For example, the probability setting 110e may indicate that the test power fault is injected into the storage device 20 at a desired rate, e.g., 20%, etc., but the example embodiments are not limited thereto.

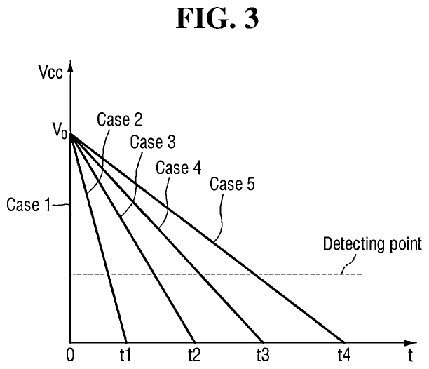

According to at least one example embodiment, the power fault injector 100 may include a fault trigger checker 120. The fault trigger checker 120 may detect a case where the storage controller 200 generates a trigger (e.g., a fault) inside the storage controller 200, etc., but the example embodiments are not limited thereto. For example, in response to the injection of a test power fault to the storage device 20, when the power received by the storage device 20 and/or received by one or more components of the storage device 20 decreases to a desired power level specified by the user (e.g., the detecting point of FIG. 3, a desired threshold voltage level, a desired sensing position, etc.) according to and/or based on the desired power fault type setting 110a, etc., the storage controller 200 recognizes and/or determines that a power fault occurs (and/or will occur) and/or determines the power fault type which occurs (and/or will occur), and may generate a trigger (e.g., a system fault, a hardware fault, an error, etc.), wherein the trigger may include information related to and/or associated with the power fault, such as the determined power fault type, a time of occurrence, a power level associated with the fault, etc., but the example embodiments are not limited thereto. When the fault trigger checker 120 detects that the storage controller 200 has generated a trigger, the test firmware 30 may perform an operation (e.g., a power fault recovery operation, a power fault response operation, etc.) according to and/or based on the occurrence of a power fault, such as safe shutdown operations, data recovery operations, etc., which are expected to be performed in the event of an actual power fault. In at least one example, the test firmware 30 may execute a desired power fault recovery operation based on the power fault type information included in the trigger, etc., but the example embodiments are not limited thereto. The host 10 and/or the user may monitor the results of the power fault recovery operation and determine whether the performance of the test firmware 30 and/or the performance of the storage device 20 operates smoothly and/or correctly in response to the occurrence of the simulated and/or test power fault.

FIG. 3 is an example graph for explaining some operation of the storage system according to some example embodiments.

Referring to FIGS. 1 to 3, according to at least one example embodiment, a time t at which the test firmware 30 is driven and/or executed may be shown on a horizontal axis, and the power supplied to the storage device 20 may be shown on a vertical axis, but the example embodiments are not limited thereto. For example, as shown in FIG. 3, the storage device 20 may be operating at an initial operating voltage, Vₒ, and may then decrease over time due to a power fault, as shown by Case 1 to Case 5, but the example embodiments are not limited thereto.

For example, when the type 110a of power fault is a SPO, the power fault injector 100 and/or the test firmware 30 may control a power supply and/or power source supplying power to the storage device 20 such that the power may be turned off immediately as shown in the graph of a first case (e.g., Case 1).

As another example, the power fault injector 100 and/or the test firmware 30 may control the power supply such that the power supplied to the storage device 20 may be turned off such that each of a second case (e.g., Case 2), a third case (e.g., Case 3), a fourth case (e.g., Case 4), and/or a fifth case (e.g., Case 5) may occur, in response to the test firmware 30 being driven up to and/or executed at a first time t1, a second time t2, a third time t3, and/or a fourth time t4, etc., but the example embodiments are not limited thereto.

When the power being supplied to and/or received by the storage device 20 for each case decreases from the initial operating voltage Vo to a sensing position (e.g., the detecting point, a desired sensing position, a desired voltage threshold, etc.) set by the user in the setting information, the operation of the test firmware 30 and/or the storage device 20 in response to the test power fault may be verified, thereby testing and/or simulating the occurrence of a power fault at the storage device 20, etc.

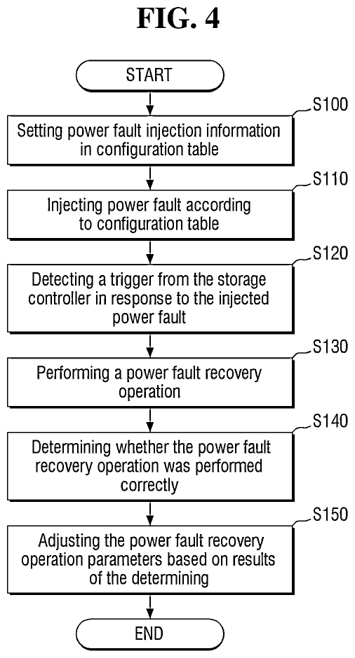

FIG. 4 is a flowchart for explaining the operating method of the storage system according to some example embodiments.

Referring to FIGS. 1 to 4, the user sets information about and/or related to power fault injection (e.g., the user sets test parameters corresponding to a test power fault, etc.) in the setting value table 110 included in the host 10 in operation S100. The information about and/or parameters for the power fault injection may be the above-mentioned setting values 110a to 110e, etc., but the example embodiments are not limited thereto.

In operation S110, the power fault injector 100 injects a power fault (e.g., a test power fault) into the storage device 20 according to and/or based on the setting values 110a to 110e recorded in the setting value table 110, or in other words, the power fault injector 100 of the host 10 may generate a test power fault based on the power fault settings (and/or user settings, etc.), and may transmit the test power fault to the storage device 20, etc.

In operation S120, the storage controller 200 receive the test power fault, and in response, may generate a trigger (and/or fault, etc.) when the power received by the storage device 20 and/or components of the storage device 20, decreases to the power value specified by the user, e.g., the desired sensing position, a desired voltage threshold, the detecting point, etc. Additionally, the fault trigger checker 120 in the host 10 senses and/or receives the trigger generated by the storage controller 200, and in operation S130, the test firmware 30 may perform an operation corresponding to the occurrence of the power fault (e.g., a power fault recovery operation, a power fault response operation, etc.), such as a safe shutdown operation, a data recovery operation, etc.

In operation S140, the user and/or the host 10 may inspect the operation of the test firmware 30 according to and/or based on the occurrence (and/or injection) of the test power fault, and may monitor whether the firmware normally performs, and/or performs as expected, the power fault recovery operations (e.g., the safe shutdown operation, the data recovery operation, etc.) at the time of the power fault. In other words, the host 10 and/or the user may determine whether the test firmware 30 properly performed the power fault recovery operation(s), etc., but the example embodiments are not limited thereto. For example, the host 10 and/or the user may determine whether the test firmware 30 and/or the storage device 20 performed the power fault recovery operation(s) properly and/or correctly by comparing the power levels of the storage device 20 after the injection of the test power fault and/or comparing faults and/or error codes generated by the storage device 20 after the injection of the test power fault to the corresponding desired and/or expected power fault tests results stored in the setting value table 110, etc. In operation S150, the host 10 and/or the user may adjust the corresponding and/or relevant power fault recovery operation(s) parameters in the test firmware 30 and/or the storage device 20 (e.g., adjust parameters associated with the tested power fault type in the storage controller 200 and/or firmware executed by the storage controller 200) based on the results of the determination, etc., but the example embodiments are not limited thereto. In other words, in response to the host 10 and/or the user determining that the test firmware 30 and/or the storage device 20 did not perform the power fault recovery operation(s) properly and/or correctly, the host 10 and/or user may adjust the power fault operation parameters of the associated and/or corresponding test power fault type stored in the test firmware 30 and/or in the storage device 20, etc.

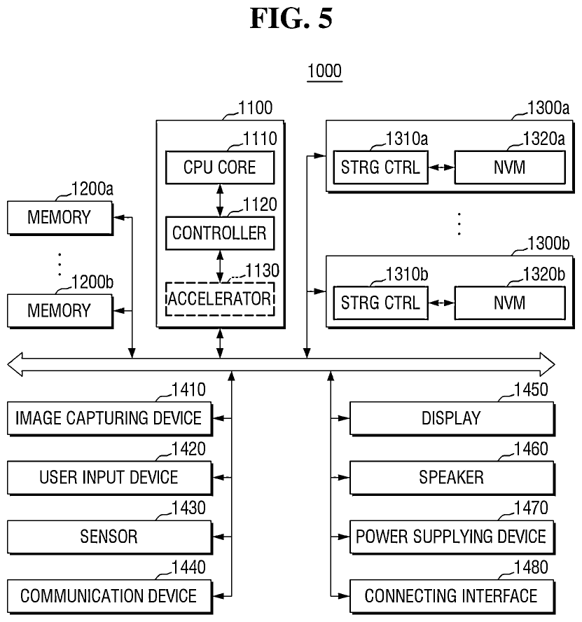

FIG. 5 is an example block diagram for explaining an electronic system to which the operation of the storage system according to some example embodiments is applied.

FIG. 5 is a diagram showing an example electronic system 1000 to which the operation of the storage system according to at least one example embodiment of the inventive concepts is applied. The system 1000 of FIG. 5 may be, for example, a mobile system, such as a mobile phone, a laptop computer, a smart phone, a tablet device (e.g., tablet smart device, etc.), a wearable device, a healthcare device, a robotic device, a virtual reality and/or augmented reality device, an autonomous vehicle, a navigation device, and/or an IOT (internet of things) device, etc., but the example embodiments are not limited thereto. However, the system 1000 of FIG. 5 is not limited to a mobile system, but may also be a stationary system, such as a personal computer, a server, a media player, and/or gaming console, etc.

Referring to FIG. 5, the system 1000 may include a main processor 1100, a plurality of memories 1200a and 1200b, and/or a plurality of storage devices 1300a and 1300b, etc., and may additionally include one or more of an image capturing device 1410, a user input device 1420, a sensor 1430, a communication device 1440, a display 1450, a speaker 1460, a power supplying device 1470, and/or a connecting interface 1480, etc., but the example embodiments are not limited thereto, and the system 100 may include a greater or lesser number of constituent components, etc.

The main processor 1100 may control the overall operations of the system 1000, more specifically, the operations of other constituent elements that make up the system 1000, etc. For example, the main processor 1100 may be implemented as at least one general purpose processor, at least one dedicated processor, one or more application processors, and/or the like, but the example embodiments are not limited thereto.

The main processor 1100 may include one or more CPU cores 1110, and may further include a controller 1120 for controlling the memories 1200a and 1200b and/or the storage devices 1300a and 1300b, etc., but the example embodiments are not limited thereto. Depending on the example embodiment, the main processor 1100 may further include an accelerator 1130 which is a dedicated circuit for a high-speed data computation such as an AI (artificial intelligence) data computation, etc. Such an accelerator 1130 may include a GPU (Graphics Processing Unit), an NPU (Neural Processing Unit) and/or a DPU (Data Processing Unit), and/or the like, and may be implemented as separate chips that are physically independent of other constituent elements of the main processor 1100, but the example embodiments are not limited thereto.

The memories 1200a and 1200b may be used as a main memory unit of the system 1000, and may include a volatile memory such as an SRAM and/or a DRAM, etc., but may also include a non-volatile memory such as a flash memory, a PRAM, a MRAM and/or a RRAM, etc. The memories 1200a and 1200b may also be implemented in the same package as the main processor 1100, etc.

The storage devices 1300a and/or 1300b may function as non-volatile storage devices for storing data regardless of whether a power is supplied, and may have a relatively larger storage capacity than the memories 1200a and/or 1200b, etc. The storage devices 1300a and 1300b may include storage controllers 1310a and 1310b, etc., and non-volatile memories (NVM) 1320a and 1320b, etc., that store data under the control of the storage controllers 1310a and 1310b. The nonvolatile memories 1320a and 1320b may include a flash memory of a 2D (2-dimensional) structure and/or a 3D (3-dimensional) V-NAND (Vertical NAND) structure, but may also include other types of non-volatile memory such as a PRAM and/or a RRAM, etc.

The storage devices 1300a and 1300b may be included in the system 1000 in a state of being physically separated from the main processor 1100, and/or may be implemented in the same package as the main processor 1100, etc. Further, since the storage devices 1300a and 1300b have a shape, such as an SSD (solid state device) and/or a memory card, the storage devices 1300a and 1300b may also be attachably and/or detachably coupled with other constituent elements of the system 1000 through an interface such as a connecting interface 1480 to be described below. Such storage devices 1300a and 1300b may be devices to which standard protocols such as a UFS (universal flash storage), an eMMC (embedded multi-media card) and/or an NVMe (non-volatile memory express), etc., are applied, but are not limited thereto.

The image capturing device 1410 may capture still images and/or moving images, and may be a camera, a camcorder, and/or a webcam, etc.

The user input device 1420 may receive various types of data that are input from users of the system 1000, and may be one or more of a touch pad, a keypad, a keyboard, a mouse and/or a microphone, the image capturing device 1410, a touchscreen, etc., but is not limited thereto.

The sensor 1430 may detect various types of physical quantities that may be acquired from the outside of the system 1000, and convert the detected physical quantities into electrical signals, etc. For example, the sensor 1430 may be one or more of a temperature sensor, a pressure sensor, an illuminance sensor, a position sensor, an acceleration sensor, a biosensor and/or a gyroscope sensor, etc., but are not limited thereto.

The communication device 1440 may transmit and/or receive signals to and from other devices outside the system 1000 according to various communication protocols. Such a communication device 1440 may be implemented to include an antenna, a transceiver and/or a modem, and/or the like.

The display 1450 and the speaker 1460 may each function as output devices that output visual and/or auditory information to the user of the system 1000, etc.

The power supplying device 1470 may appropriately convert the power supplied from, for example, a battery (not shown), etc., equipped in the system 1000, and/or an external power supply, and supply the power to each constituent element of the system 1000.

The connecting interface 1480 may provide a connection between the system 1000 and an external device that may be connected to the system 1000 to transmit and/or receive data to and/or from the system 1000. The connecting interface 1480 may be implemented in various interface types, such as an ATA (Advanced Technology Attachment), a SATA (Serial ATA), an e-SATA (external SATA), a SCSI (Small Computer Small Interface), a SAS (Serial Attached SCSI), a PCI (Peripheral Component Interconnection), a PCIe (PCI express), a NVMe, an IEEE 1394, a USB (universal serial bus), an SD (secure digital) card, a MMC (multi-media card), an eMMC, a UFS, an eUFS (embedded Universal Flash Storage), and/or a CF (compact flash) card interface, etc., but the example embodiments are not limited thereto.

Although various example embodiments of the inventive concepts have been described above with reference to the accompanying drawings, it will be understood by those of ordinary skill in the art that the example embodiments are not limited thereto and may be implemented in many different forms without departing from the inventive concepts. Therefore, it should be understood that the example embodiments set forth herein are merely examples in all respects and not restrictive.

What is claimed is:

1. A storage system comprising:
a host device including processing circuitry;
a storage device configured to communicate with the host device; and
the processing circuitry is configured to,
generate a test power fault based on power fault setting information stored in a setting value table, and
inject the test power fault into the storage device based on the power fault setting information.

2. The storage system of claim 1, wherein the processing circuitry is further configured to:
detect a trigger generated by the storage device in response to the injected test power fault.

3. The storage system of claim 2, wherein the processing circuitry is further configured to:
perform a power fault recovery operation associated with a detected power fault type in response to the detected trigger, the detected power fault type included in the detected trigger.

4. The storage system of claim 1, wherein at least one of the power fault setting information is information related to a desired test power fault type setting, the desired test power fault type setting indicating a type of test power fault to be generated by the host device.

5. The storage system of claim 4, wherein the desired test power fault type is at least one of a SPO (Sudden Power oft), a NPO (Normal Power Oft), a LVDF (Low Voltage Fault F), a LVDH (Low Voltage Fault H), or any combinations thereof.

6. The storage system of claim 1, wherein at least one of the power fault setting information is a desired time point setting, the desired time point indicating a time at which the test power fault is injected into the storage device.

7. The storage system of claim 1, wherein at least one of the power fault setting information is a desired position setting, the desired position setting indicating a component of the storage device where the test power fault occurs.

8. The storage system of claim 1, wherein at least one of the power fault setting information is a desired occurrence setting, the desired occurrence setting indicating a number of times the test power fault occurs.

9. The storage system of claim 1, wherein at least one of the power fault setting information is a desired probability setting, the desired probability setting indicating a probability rate at which the test power fault occurs.

10. A storage system comprising:
processing circuitry configured to execute computer readable instructions to,
generate a test power fault based on power fault setting information; and
inject the test power fault into a storage device.

11. The storage system of claim 10, wherein the processing circuitry is further configured to:
detect a trigger generated by the storage device in response to the injected test power fault.

12. The storage system of claim 11, wherein the processing circuitry is further configured to:
perform a power fault recovery operation corresponding to a detected power fault type in response to the detected trigger, the detected power fault type included in the trigger.

13. The storage system of claim 10, wherein at least one of the power fault setting information is information related to a desired test power fault type setting, the desired test power fault type setting indicating a type of test power fault to be generated by the processing circuitry.

14. The storage system of claim 13, wherein the desired test power fault type is at least one of a SPO (Sudden Power oft), a NPO (Normal Power Oft), a LVDF (Low Voltage Fault F), a LVDH (Low Voltage Fault H), or any combinations thereof.

15. The storage system of claim 10, wherein at least one of the power fault setting information is a desired time point setting, the desired time point indicating a time at which the test power fault is injected into the storage device.

16. The storage system of claim 10, wherein at least one of the power fault setting information is a desired position setting, the desired position setting indicating a component of the storage device where the test power fault occurs.

17. The storage system of claim 10, wherein at least one of the power fault setting information is a desired occurrence setting, the desired occurrence setting indicating a number of times the test power fault occurs.

18. The storage system of claim 10, wherein at least one of the power fault setting information is a desired probability setting, the desired probability setting indicating a probability rate at which the test power fault occurs.

19. A method for operating a storage system, the method comprising:
storing, using processing circuitry, power fault setting information related to test power fault injection settings in a setting value table included in a host device;
generating, using the processing circuitry, a test power fault based on the stored power fault setting information;
injecting, using the processing circuitry, the test power fault into a storage device in accordance with the stored power fault setting information;
detecting, using the processing circuitry, a trigger generated by the storage device in response to the injected test power fault; and
inspecting, using processing circuitry, a recovery operation executed at the storage device in response to the test power fault.

20. The method for operating the storage system of claim 19, wherein the setting value table includes at least one of:
a desired power fault type setting, a desired time point setting indicating a time at which the test power fault occurs, a desired position setting indicating at least one component of the storage device where the test power fault occurs, a desired occurrence setting indicating a number of times the test power fault occurs, a desired probability rate setting indicating a desired probability that the test power fault occurs.
